(19) United States
(12) Patent Application Publication
(10) Pub. No.: US 2012/0024959 A1
(43) Pub. Date: Feb. 2, 2012

(54) RFID INLET AND RFID TAG, AND METHOD FOR MANUFACTURING RFID INLET AND RFID TAG

(76) Inventors: Madoka MINAGAWA, Yokohama (JP); Naoya KANDA, Fujisawa (JP); Isao SAKAMA, Hiratsuka (JP); Shigeru SAGAWA, Yokohama (JP); Daisuke SHIBATA, Yokohama (JP)

(21) Appl. No.: 13/077,390

(22) Filed: Mar. 31, 2011

(30) Foreign Application Priority Data
Jul. 29, 2010 (JP) 2010-170578

(51) Int. Cl. G06K 19/077; H01L 21/98

(52) U.S. Cl. 235/488; 438/118; 257/E21.705

(57) ABSTRACT

An RFID inlet by including: a base film; an antenna pattern formed on the base film; an insulation film layer formed on the antenna pattern and having a hole; an IC chip coupled to the antenna pattern inside the hole of the insulation film layer; and an underfill filled between the IC chip, the antenna, and the base film. The height of the IC chip top surface is at a higher level than the top surface of the insulation film layer, the underfill is formed between the IC chip and a wall surface of the hole of the insulation film layer.

### BACKGROUND

The present invention relates to an RFID inlet and RFID tag which has its upper surface or back surface, or upper/back surfaces printed for use, and a method for manufacturing the RFID inlet and RFID tag. More particularly, the present invention provides a structure intended to planarize the upper or the back surface by smoothing out the surface irregularity, which may interfere with printing and deteriorate printing quality.

Recently, the RFID (Radio Frequency Identification) tag processed into a label or a card, and attached to the article has been widely used for managing information of the article. The RFID tag is manufactured by adhering film or paper to the upper surface or the back surface of a structure called inlet or inlay, which is formed of an IC chip and an antenna via an adhesive agent or pressure-sensitive adhesive agent, in accordance with the object and usage.

Various types of information such as ID (Identification: identification information) stored in the IC chip may be transmitted to and received from a reader-writer wirelessly via the antenna. The reader-writer has been used for conducting various types of product management by allowing contactless reading of the information stored in the IC chip or writing of the information into the IC chip. In most cases, the RFID tag is matched with the information of the product to which the tag is attached, and the product information is printed on the surface of the tag so as to be visually confirmed by the human. It is often used for backup in case the ID is unreadable.

For the reason as described above, the upper or back surface of the RFID tag is generally configured to be printable. The sheet called “rewritable sheet with built-in RFID” contains the RFID therein, and has a rewritable layer on its surface, which can be used through thermal performance of printing and deleting of information with repetition by approximately 1000 times.

In the aforementioned environment of usage, the RFID tag is designed to have required information printed using various types of printers. In case of irregularity on the printing surface upon printing, problems such as deterioration of printing quality, printing failure, and damaged printing surface may occur. Especially, as the thickness of the IC chip is at least equal to 30 μm or larger, the point at which the IC chip exists may be thicker than the remaining portion. This may cause the risk of breaking the IC chip. So the upper surface of the RFID tag has to be planarized.

Japanese Unexamined Patent Publication No. 2008-9881 discloses technology for planarizing the RFID tag surface. The disclosed method uses a film layer 912 shown in FIG. 9A having a cut part corresponding to an IC chip 94 which is bonded to an antenna 91 on a base film 92 via a solder 95 and coated with an underfill 96 therearound as illustrated in FIG. 9B.

In the method for manufacturing an IC tag inlet as disclosed in Japanese Unexamined Patent Publication No. 2008-102805, the IC chip is mounted on a base material provided with an antenna, and further buried therein while being pressurized so as to prevent generation of the irregularity on the surface of the base material owing to the IC chip thickness.

If planarization is performed according to the method according to the second embodiment disclosed in Japanese Unexamined Patent Publication No. 2008-9881, the area of the structure shown in FIG. 9B, which is coated with the underfill 96 has to be entirely cut. Accordingly, the film layer 912 with a large hole as shown in FIG. 9A is required. When the film layer 912 is brought into contact with the fillet end of the underfill 96, it is raised by height equivalent to the underfill thickness, thus preventing planarization.

The amount for applying the underfill 96 is normally controlled based on volume of the material supplied from the syringe. However, it is difficult to accurately control the coating region (area) because of flowability which differs resulting from slight difference of the temperature, humidity, and lot. As the underfill coating area differs depending on the sample, the area of the film layer to be cut for planarization has to be set to maximum area of the underfill. The resultant area has to be markedly larger than the chip area, thus enlarging the space defined by the chip end and the film layer large. Such portion has no base, and becomes unstable with respect to the printing operation, thus forming an unprintable region.

In the method disclosed in Japanese Unexamined Patent Publication No. 2008-102805, the region of the base material around the portion where the IC chip is buried is dented. The resultant area on the IC tag surface as the unprintable region is unnecessarily larger than the buried IC chip.

### SUMMARY

After the investigation performed by the inventors with respect to the region coated with the underfill using 0.4 mm×0.4 mm IC chip, it is revealed that the region coated with the underfill measured from the chip end varies in the range from approximately 0.3 mm to 1.2 mm. Due to the large difference as described above, generally, the cut portion of the chip of the shaping layer 912 has to be formed as the hole with a diameter of approximately 5 mm, which contains the positioning region. In most cases, the IC chip is designed to be positioned at the center of the tag, and accordingly, the unprintable region with diameter of approximately 5 mm exists in the center of the tag. As the IC chip becomes large, the unprintable region is proportionally enlarged. It is therefore necessary to control the region coated with the underfill for making the unprintable region as small as possible.

It is an object of the present invention to provide a planarized RFID tag with its upper or back surface or upper/back surfaces printed for use by removing the unprintable region. The sheet which can be repeatedly used for printing and deleting by heat, which is so called RFID rewritable sheet, needs to be resistant to printing operations performed 1000 times or more. Especially, the printing surface of such sheet has to be planarized.

To solve the above problem in accordance with the present invention, the present invention provides an RFID inlet by including: a base film; an antenna pattern formed on the base film; an insulation film layer formed on the antenna pattern and having a hole; an IC chip coupled to the antenna pattern inside the hole of the insulation film layer; and an underfill filled between the IC chip, the antenna, and the base film. The height of the IC chip top surface is at a higher level than the top surface of the insulation film layer, the underfill is formed between the IC chip and a wall surface of the hole of the insulation film layer.

In addition, to solve the above problem in accordance with the present invention, the present invention provides an RFID tag by including: a shaping layer having a window and placed on the insulation film layer so as for the IC chip to be mounted inside the window; a buffer material filled between the IC chip and the shaping layer inside the window of the shaping layer; and a printing layer placed on the shaping layer and the IC chip.

To solve the above problem, the present invention provides a method of forming an RFID inlet by including: forming an antenna pattern by applying a resist on a base film on which a material for the antenna pattern is formed, exposing the resist through a mask, and etching the exposed resist to form the antenna pattern with the material fro the antenna pattern; partially removing the resist from the antenna pattern where an IC chip is to be mounted; mounting and bonding the IC chip onto the antenna pattern where the resist is partially removed; and filling an underfill material into gaps between the IC chip and the antenna pattern, the IC chip and the base film, and the IC chip and the resist.

Furthermore, to solve the above problem in accordance with the present invention, the present invention provides a method for forming an RFID tag by including: bonding a shaping layer, which has a window in a portion corresponding to the top surface of the IC chip and has a height of the surface approximately as high as the height of the surface of the IC chip, to the resist of the RFID inlet manufactured by the above method of forming an RFID; filling a buffer material into gaps between the shaping layer, the base film and the IC chip; and bonding a printing layer to the shaping layer and the IC chip so as to cover surfaces of the shaping layer and the IC chip.

The present invention allows the upper or back surface of the RFID tag to be planarized so as to remove an unprintable region on the upper or back surface.

These features and advantages of the invention will be apparent from the following more particular description of preferred embodiments of the invention, as illustrated in the accompanying drawings.

### BRIEF DESCRIPTION OF THE DRAWINGS

FIG. 1 is a sectional view of an RFID tag according to first and second embodiments, which illustrates its structure;

FIG. 2A illustrates a flowchart of a process for manufacturing an antenna of an RFID inlet using a printing resist, and sectional views each showing a structure of the RFID tag in respective steps according to the first and second embodiments;

FIG. 2B is a perspective view of the RFID tag which has been processed up to a step of removing the resist according to the first and the second embodiments;

FIG. 3 illustrates a flowchart of a process for manufacturing the RFID inlet, and sectional views each showing a structure of the RFID tag in the respective steps according to the first to third embodiments;

FIG. 4A illustrates a flowchart of a process for manufacturing the RFID tag, and sectional views each showing a structure of the RFID tag in the respective steps according to the first to the third embodiments;

FIG. 4B is a perspective view of a shaping layer according to the first to the third embodiments;

FIG. 5 illustrates a flowchart of a process for manufacturing an antenna for the RFID inlet using a resist of positive/negative type, and sectional views each showing the structure of the RFID tag in the respective steps according to the second embodiment;

FIG. 6 illustrates a flowchart of a process for manufacturing the antenna for the RFID inlet of film stick type, and sectional views each showing the structure of the RFID tag in the respective steps according to the third embodiment;

FIG. 7 illustrates a flowchart of a process for manufacturing the RFID tag having no antenna provided on the entire surface below the IC chip, and sectional views each showing the structure of the RFID tag in the respective steps according to a fourth embodiment;

FIG. 8 is a sectional view of a structure of the RFID tag according to a fifth embodiment;

FIG. 9A is a perspective view as an overview of a film layer of the RFID tag as related art; and

FIG. 9B is a sectional view of the structure of the RFID tag as related art.

### DESCRIPTION OF THE PREFERRED EMBODIMENTS

Embodiments of the present invention will be described referring to the drawings.

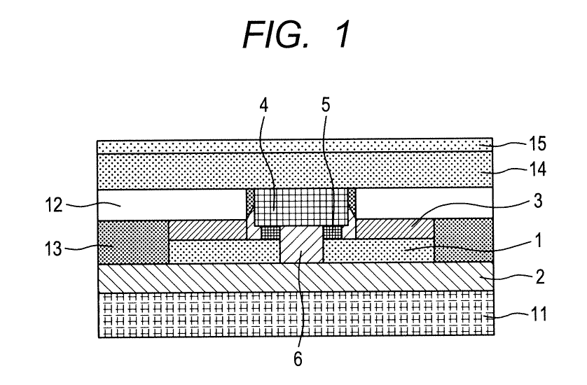

FIG. 1 illustrates a structure of layers for forming an RFID tag according to the present invention.

The RFID tag according to the present invention is formed of a base film 2 adhered onto a base layer 11, an antenna 1 formed on the base film 2, a buffer layer 13 for surrounding periphery of the antenna 1, a resist layer 3 formed to cover the antenna 1 inside the buffer layer 13, an IC chip 4 bonded to the antenna 1 via a solder bump 5, a shaping layer 12 which surrounds the IC chip 4 and having the same surface height level with the IC chip 4 for flatting the surface levels with the IC chip 4, a printing layer 14 formed for covering surfaces of the IC chip 4 and the shaping layer 12, and a protective layer 15 for covering the surface of the printing layer 14.

An RFID inlet 10 is formed of the base film 2, the antenna 1 formed thereon, and the IC chip 4 bonded to the antenna 1 via the solder bump 5.

The process for manufacturing the RFID tag is mainly comprising (1) the process for manufacturing the RFID inlet 10 having an underfill coating control region and (2) the process for manufacturing a planarized RFID tag.

In the process (1) for manufacturing the RFID inlet having the underfill coating control region, the resist for manufacturing the antenna for the RFID inlet is used, and the resist on the underfill coating control region is removed while leaving the residual resist to manufacture the RFID inlet with the underfill coating control region. The film with the cut portion corresponding to the underfill coating control region may be attached to manufacture the RFID inlet.

Generally, the size of the hole cut in the shaping layer 12 for filling resist to surround the IC chip 4 to be the same surface height level has to be set to the area several tens times larger than the IC chip. However, the use of the RFID inlet 10 with the underfill coating control region minimizes the area of the hole. All the regions of the antenna of the RFID inlet are protected by the resist and the underfill, thus enhancing mechanical strength such as bending and tensile strength. By covering the antenna with the insulator, the IC chip is protected from destruction caused by static electricity. This makes it possible to manufacture the RFID tag with higher strength than the generally employed RFID tag.

In the process (2) for manufacturing the planarized RFID tag, an RFID tag base layer 11 as a base for supporting the RFID inlet 10 with the underfill coating control region is adhered to the lower layer thereof when needed. The shaping layer 12 having a hole which has an area equivalent to that of the underfill coating control region, and a thickness which is equivalent to the height of the IC chip 4 is adhered to the upper layer of the RFID inlet 10 for planarizing the IC chip 4. The upper surface of the shaping layer 12 has the same height as that of the upper surface of the IC chip 4, thus planarizing the surface of the RFID tag. The buffer layer 13 is provided, which flows on the shaping layer 12 and the IC chip 4 and fills in the hole 121 around periphery of the IC chip 4. The buffer layer 13 allows printing on the upper layer of the upper surface of the IC chip. The printing layer 14 is formed on the shaping layer 12. When needed, the protective layer 15 of the printing layer 14 may be provided.

Embodiments each for manufacturing the RFID tag with the structure shown in FIG. 1 will be described.

### First Embodiment

A first embodiment will be described.

The process (1) for manufacturing the RFID inlet 10 with the underfill coating control region of the process for manufacturing the RFID tag as described above may further be divided into process (1-1) for manufacturing the RFID antenna with the underfill coating control region, and process (1-2) for manufacturing the RFID inlet by mounting the IC chip, and coating/baking the underfill. Each step of the above-described processes will be described in detail.

(1-1) Process for Manufacturing RFID Antenna with Underfill Coating Control Region

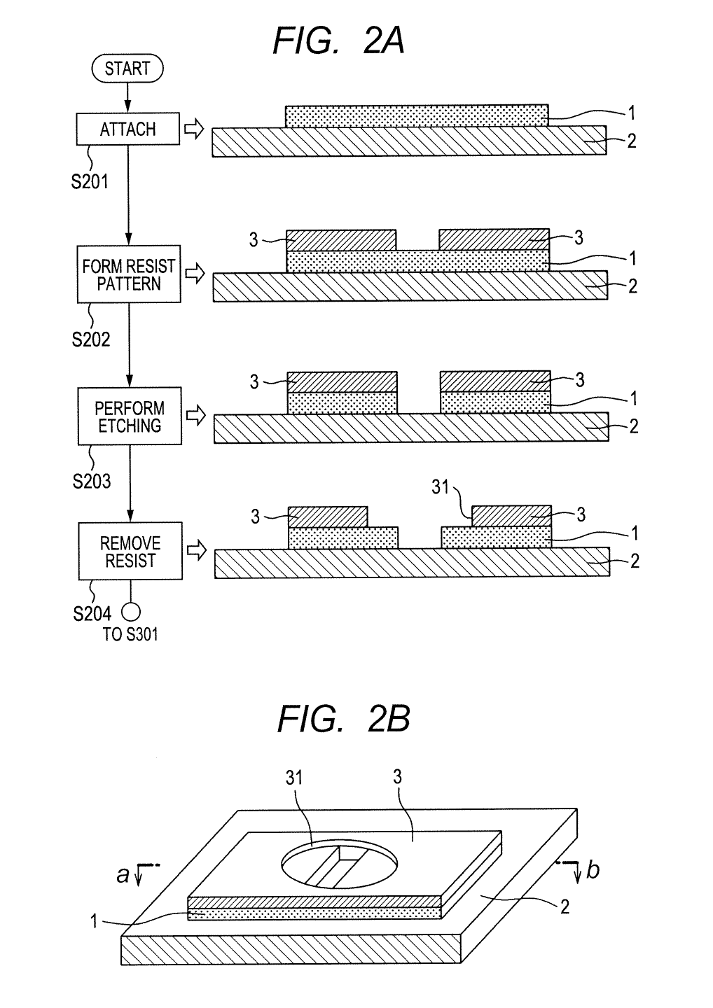

The process for manufacturing the RFID antenna with the underfill coating control region according to the exemplary embodiment will be described in detail referring to FIGS. 2A and 2B. FIG. 2A shows respective steps and sectional views of the element structure corresponding to the respective steps.

Firstly in S201, as an antenna 1, an aluminum foil 1 with a thickness of 20 μm is adhered to a base film 2 formed of a PET (Polyethylene Terephthalate) or a PEN (Polyethylene Naphthalate) with thickness of 25 μm via an adhesive agent. Then an antenna pattern is printed with a rotary plate for gravure printing using a resist, for example, a vinyl chloride-vinyl acetate copolymer in S202. The printing thickness of the resist for normal antenna etching process is approximately in the range from 4 to 6 μm. In the exemplary embodiment, the thickness of the resist layer 3 is controlled in accordance with the coating area to be controlled for forming the underfill coating control region. For example, the thickness is set to 10 μm twice as large as the normal coating thickness. If it is desired to further reduce the underfill coating region, the coating thickness may be increased. The antenna pattern may be printed not only through the gravure printing but also screen printing.

Alternatively, the antenna pattern may be formed using liquid photoresist of positive or negative type or dry film through general photoetching technique. After manufacturing the antenna pattern of the resist, the aluminum is etched in S203. In this case, the aluminum is used as the material for forming the antenna. However, copper foil may be used for forming the antenna through the similar method.

Thereafter, generally, all the resist on the surface is removed. However, in the exemplary embodiment, the resist layer 3 on the region desired to be coated with the underfill after mounting the IC chip is only removed in S204. The resist is removed through excimer laser irradiation. FIG. 2B shows the perspective view of the element in S204 of FIG. 2A. A hole 31 with circular shape formed by removing the resist at the center of the resist layer 3 shown in FIG. 2B becomes the underfill coating control region. The sectional view taken along the line a-b of FIG. 2B corresponds to the one showing the structure of the element shown in step S204 of FIG. 2A.

By the experimental study, the area coated with the underfill in the case where the underfill coating region is not controlled, it has been revealed that the underfill extends to the area approximately 10 times as large as the chip area. Accordingly, reduction of the region coated with the underfill to be half or smaller is effective for the planarization.

When increasing the thickness of the resist layer 3 to be the same thickness with the IC chip 4, a possibility of taking bubbles inside the underfill 6 upon coating becomes high. It is therefore preferable to set the thickness of the resist layer 3 to be smaller than that of the IC chip 4.

### (1-2) Process for Mounting Chip and Coating Underfill

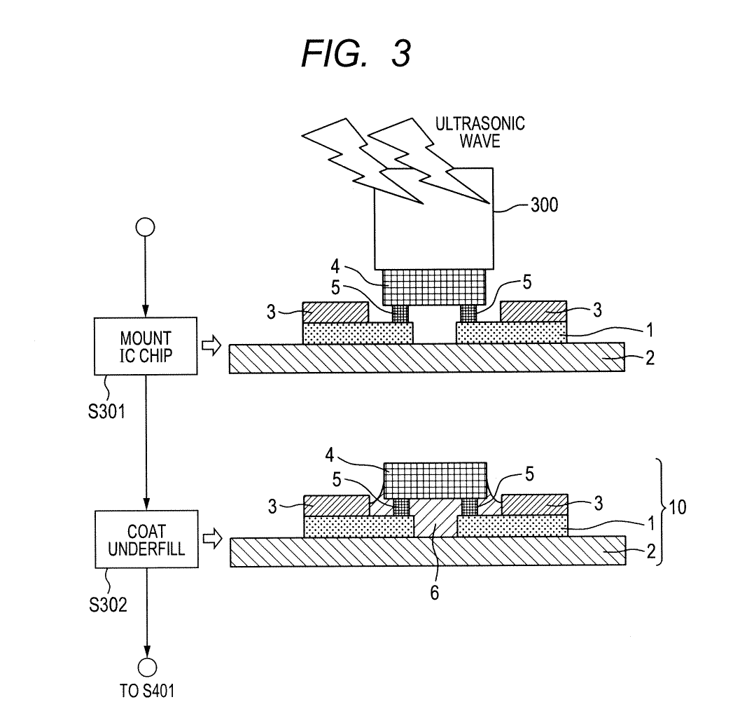

The process for mounting the chip and coating the underfill will be described referring to FIG. 3. In S301, the IC chip 4 having the solder bump 5 adhered to the connecting electrode portion is mounted on and bonded to the antenna 1 which has been manufactured through the respective steps as described in the process (1-1) under control of the underfill coating region. The IC chip 4 is bonded to the antenna 1 by irradiating an ultrasonic horn 300 on the upper surface of the IC chip 4 mounted on the antenna 1 for applying pressure and ultrasonic wave. Ultrasonic oscillation melts the solder bump 5 to bond the IC chip 4 and the aluminum antenna 1. In the aforementioned state, the IC chip 4 is not separated from the antenna 1. However, the underfill 6 is coated to intensify the bonding strength in S302. If the IC chip 4 is small, it is preferable to use the underfill 6 which does not contain the filler. The underfill 6 fills the slit between the IC chip 4 and the antenna 1 by the amount so as not to cross over the wall surface of the resist layer 3. The underfill 6 is cured to manufacture the inlet 10 (structure corresponding to step S302) with the underfill coating control region.

The IC chip 4 may be mounted and bonded through the connection method using not only ultrasonic wave but also ACF (Anisotropic Conductive Film), ACP (Anisotropic Conductive Paste), NCF (Non-conductive Film), NCP (Non-conductive Paste) and the like.

### (2) Process for Manufacturing Planarized RFID Inlet for Printing Operation

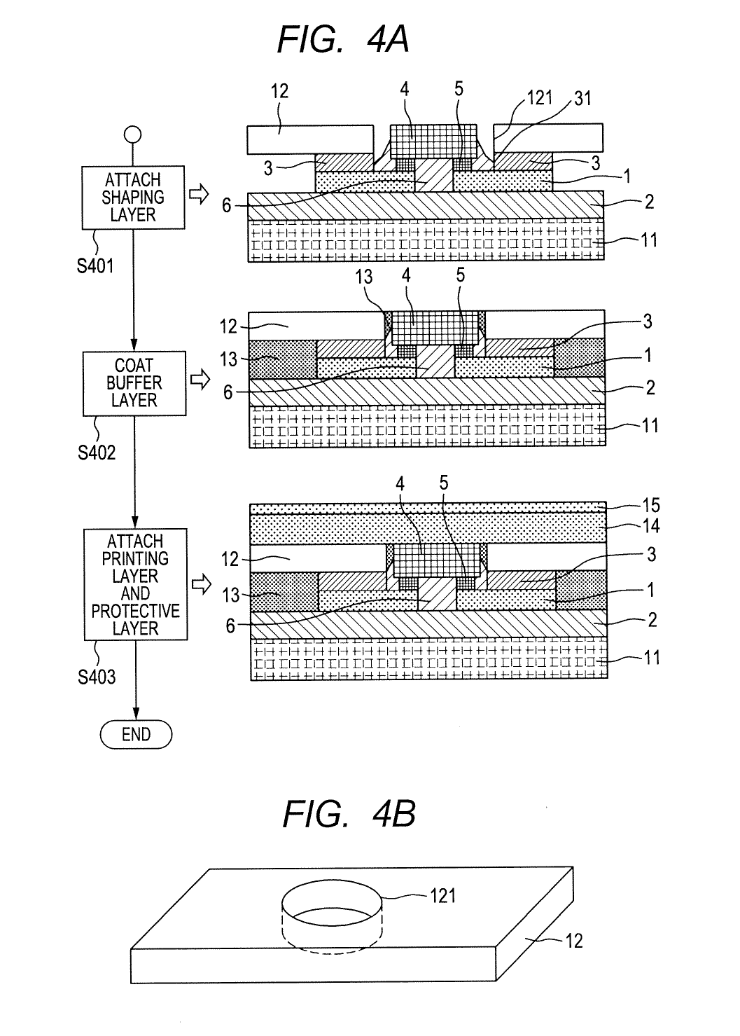

The process for manufacturing the planarized RFID inlet for printing operation will be described referring to FIGS. 4A and 4B. In the process, the planarized RFID inlet for printing operation is manufactured using the inlet 10 with the underfill coating control region, which has been manufactured in the process (1-2) as described above.

Referring to FIG. 4A, a layer 13 to be formed as the base is applied on the lower layer of the RFID inlet 10, and the shaping layer 12 for planarizing the IC chip is adhered to the upper layer of the inlet 10 while performing positioning in S401. The shaping layer 12 has a hole 121 at the center as shown by the perspective view in FIG. 4B. The hole 121 has the same area as that of the underfill coating control region formed as the hole 31 of the resist layer 3 to improve planarizing property of the RFID tag. If the lower surface of the inlet 10 is used as the printing surface, the base layer 11 of the RFID tag serves as the printing surface. In such a case, printable material is used for the base layer 11.

Then the buffer layer 13 which flows to fill the hole 121 of the shaping layer 12 is coated in S402. The buffer layer 13 may be formed of any type of material so long as it is capable of flowing to fill the hole 121, for example, the hot-melt resin such as polyester, olefin, rubber, and EVA (ethylene-vinyl acetate copolymer), the thermoplastic resin such as ABS resin, polypropylene resin, polyethylene resin, polystyrene resin, acrylic resin, vinyl chloride resin, polyisobutylene resin, polysulfide resin, and urethane resin, the thermosetting resin such as phenol resin, epoxy resin, and polyester resin, and the like. The buffer layer 13 may be used as the adhesive agent for adhering the shaping layer 12 to the RFID inlet 10.

After filling the hole 121 with the buffer layer 13, the buffer layer 13 is cured. In case the buffer layer 13 is formed of the hot melt resin, the hot melt resin is cured at room temperature. In case the buffer layer 13 is formed of the thermosetting resin, the thermosetting resin is cured at the curing temperature. Then the printing layer 14 is attached to the upper layer in S403. If the RFID rewritable sheet is used for the printing layer 14, it serves as the rewriting layer. The protective layer 15 may further be provided if needed.

According to the exemplary embodiment, the upper or the back surface of the RFID tag is planarized, thus eliminating the unprintable region on the upper or the back planarized surface. And it also provides an RFID tag which withstands the mechanical stress such as bending and tensile strength resulting from repetitive use.

### Second Embodiment

A second embodiment of the present invention will be described.

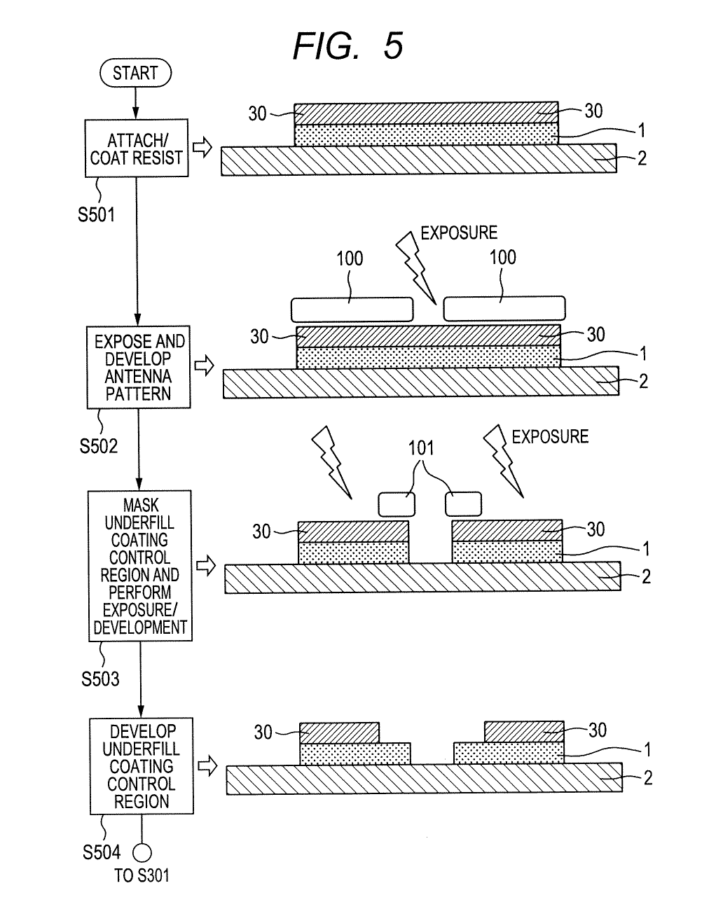

The second exemplary embodiment is formed by partially changing the process (1-1) for manufacturing the RFID antenna with the underfill coating control region as described in the first embodiment. The detailed example will be described referring to FIG. 5.

The second exemplary embodiment is manufacturing the RFID inlet 10 by controlling the underfill coating region using the resist of positive/negative type. The photoresist is generally divided into the negative type and the positive type, either of which is selected for the usage. The photoresist of positive/negative type is configured to reversibly switch the type between the positive and the negative in accordance with the exposure radiation source, intensity of the exposure light and developer.

Referring to FIG. 5, a metal foil to be formed as the antenna 1 is adhered to the base material (base film) 2. A reversibly switchable positive-type resist layer 30 is further coated in S501. The coated resist layer 30 is dried, and the antenna pattern corresponding to the portion to be removed after etching is exposed by using a mask 100 and developed in S502. The metal foil is etched to form a configuration of antenna 1. Thereafter, the area for controlling the underfill coating region is shielded using a mask 101, and the resist layer 30 corresponding to the portion other than the area for controlling the underfill coating region is exposed in S503. At this time, the intensity of the exposure light is increased to allow the reversibly switchable positive type resist layer 30 to serve as the negative type. The resist corresponding to the underfill coating control region is removed by development in S504. The method for manufacturing the RFID subsequent to the aforementioned process is the same with that of the RFID tag manufacturing process from S301 according to the first embodiment.

### Third Embodiment

A third embodiment of the invention will be described.

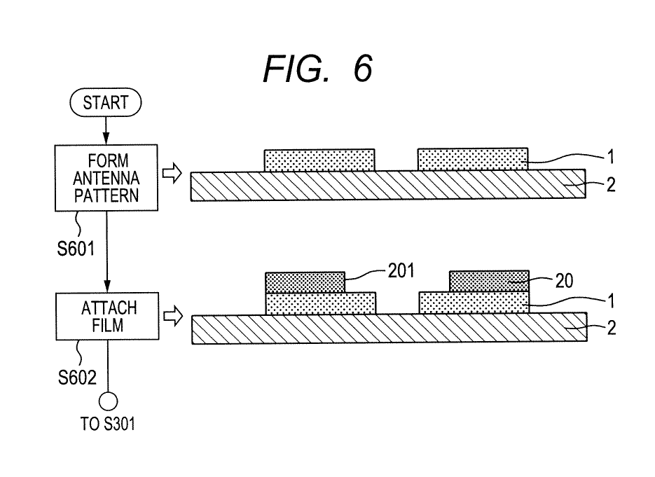

The third exemplary embodiment is formed by partially changing the process (1-1) for manufacturing the RFID antenna with the underfill coating control region as described in the first embodiment. The detailed example will be described referring to FIG. 6.

In the case where the antenna 1 is formed on the base material (base film) 2 of the RFID inlet through screen printing using the paste such as silver paste, the resist is not used for forming the antenna 1 in S601. The resist layer 3 or 30 as described in the first or the second embodiment may be applied to the antenna. But, adhering the film 20 with the hole 201 for controlling the underfill coating region is preferable in considering the property of the antenna 1 in S602. In the case the antenna 101 is formed through screen printing, a large number of voids are contained in the antenna which will be infiltrated with the resist to change the dielectric constant, which may cause the risk of deteriorating the antenna property.

The PET film, PEN film and the like which is equivalent to the film for forming the antenna base material may be used as the film 20 to be adhered. Alternatively, an arbitrary material is available so long as it can be processed to have the hole. The thickness of the film is set to be smaller than that of the IC chip so as to form the structure which prevents generation of voids in the underfill coated after mounting the IC chip.

### Fourth Embodiment

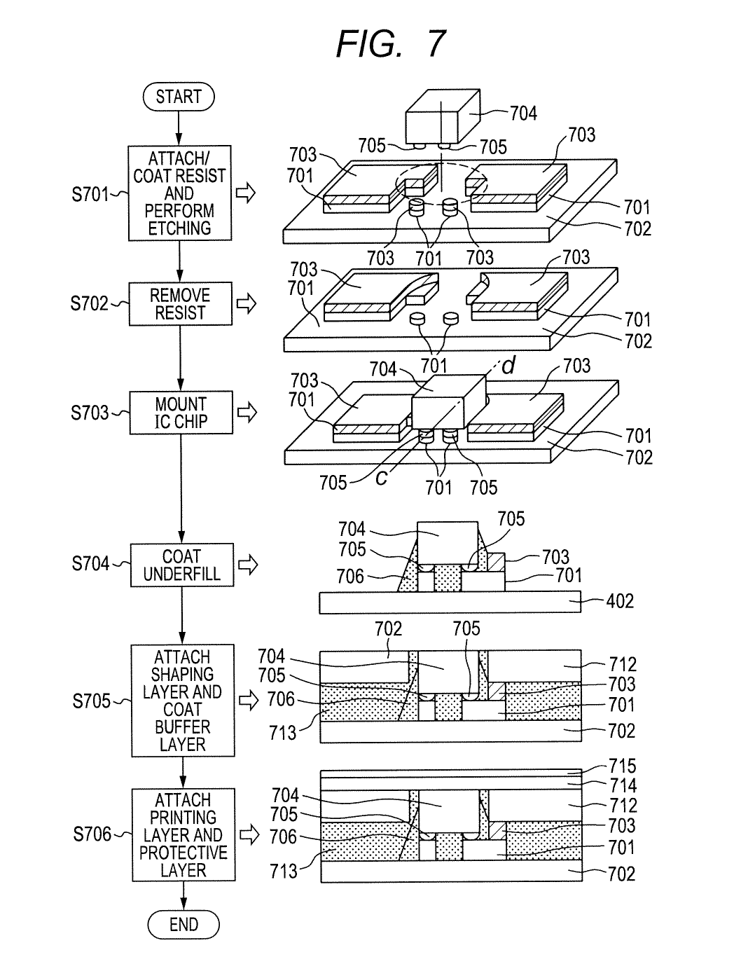

A fourth embodiment according to the present invention will be described referring to FIG. 7.

This is an example that the metal foil to be formed as the antenna of the RFID inlet does not exist on the entire surface but just below the chip compared with the structure of the RFID tag as described in FIG. 1.

The surface of the structure with the above-configured antenna may be planarized through the same process as described in the first embodiment so as to form the RFID tag with high reliability, which allows printing in good condition.

Referring to FIG. 7, the metal foil as the material for forming the antenna is attached to a base film layer 702, and a resist 703 is coated thereon. The resist 703 is exposed using a mask (not shown). It is further developed, and then etched to form an antenna pattern 701 on the base film layer 702 in S701. Then the resist 703 on the antenna pattern 701 at the portion on which an IC chip 704 is mounted is removed in S702. The IC chip 704 is then mounted on the antenna pattern 701 having the resist removed and exposed. The ultrasonic horn (not shown) is touched to the IC chip 704 to melt a solder bump 705 adhered to the IC chip 704 so that the IC chip 704 and the antenna pattern 701 are bonded in S703.

An underfill 706 is applied to the portion defined by the periphery of the IC chip 704 which is bonded to the antenna pattern 701 and the base film layer 702 in S704. At this time, the underfill coating control region is formed by the residual resist 703 around the region where the IC chip 704 is mounted to suppress spread of the applied underfill. The underfill 706 is applied so as not to be higher than the surface of the resist layer 703. A shaping layer 712 having a window (hole) which is slightly larger than the IC chip 704 is attached to the resist layer 703, and a buffer layer 713 is coated in S705. A printing layer 714 is further attached to the surface of the shaping layer 712, and a protective layer 715 is further attached thereto to form the RFID tag.

In the embodiment, attachment of the layer corresponding to the base layer 11 in the structure of the RFID tag shown in FIG. 1 is omitted. However, the base film layer 702 may be attached to a layer corresponding to the base layer 11 if needed.

The present invention is applicable to the antenna of an arbitrary configuration without being influenced thereby.

### Fifth Embodiment

A fifth embodiment of the present invention will be described.

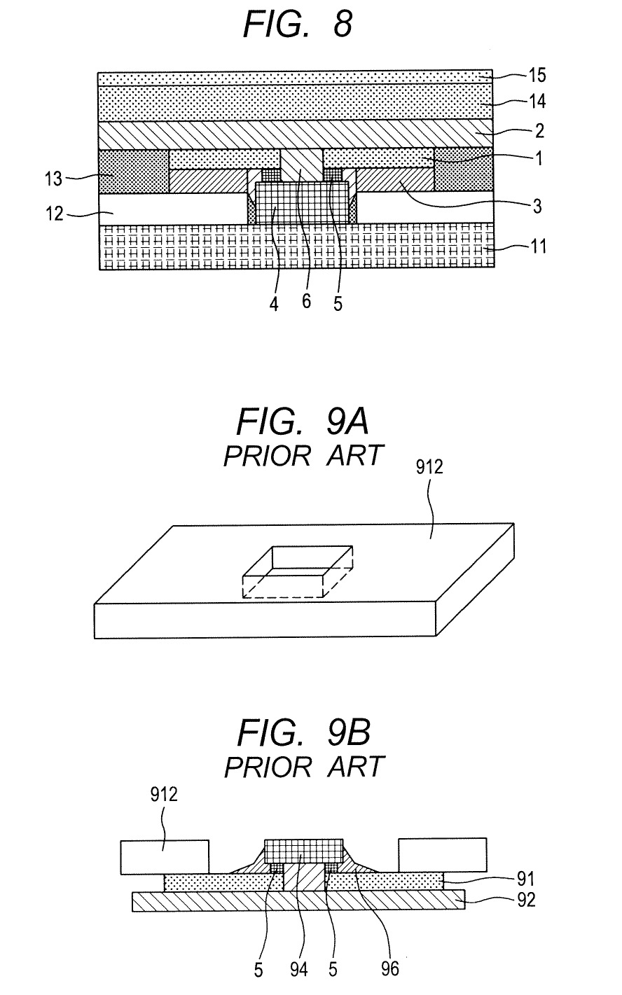

In the case of performing the process (2) for manufacturing the planarized RFID inlet for printing operation as described in the first embodiment using the RFID inlet 10 manufactured through the process arbitrarily selected from the first, second, third and fourth embodiments, the IC chip 4 of the RFID inlet 10 is directed downward as shown in FIG. 8. The shaping layer 12 is positioned at the lower portion of the RFID inlet 10. However, the printing layer 14 and the protective layer 15 may be formed above the RFID inlet 10.

In the fifth exemplary embodiment, the RFID inlet 10 formed through the process as described referring to FIGS. 2A and 3 is used, and in step S401 of the process represented in FIG. 4A, the shaping layer 12 and the base layer 11 are attached to the RFID inlet 10. However, according to the fifth exemplary embodiment, in a step corresponding to S401, the shaping layer 12 is only attached, and the buffer layer 13 is applied in a step corresponding to S402. Then in a step corresponding to S403, the printing layer 14 is attached to the surface of the base film 2, on which the protective layer 15 is attached. Meanwhile, the RFID tag with the structure as shown in FIG. 8 is formed by attaching the base layer 11 to the surface of the shaping layer 12.

According to the fifth exemplary embodiment, the printing layer 14 is attached to the surface of the base film 2, thus improving planarizing property of the surface of the printing layer 14 compared with the first to fourth embodiments.

The invention may be embodied in other specific forms without departing from the spirit or essential characteristics thereof. The present embodiment is therefore to be considered in all respects as illustrative and not restrictive, the scope of the invention being indicated by the appended claims, rather than by the foregoing description, and all changes which come within the meaning and range of equivalency of the claims are therefore intended to be embraced therein.

What is claimed is:

1. An RFID inlet comprising:
a base film;
an antenna pattern formed on the base film;
an insulation film layer formed on the antenna pattern and having a hole;
an IC chip coupled to the antenna pattern inside the hole of the insulation film layer; and
an underfill filled between the IC chip and the antenna, and the IC chip and the base film;
wherein the height of a top surface of the IC chip is at a level higher than a top surface of the insulation film layer, and the underfill is formed between the IC chip and a wall surface of the hole of the insulation film layer.

2. The RFID inlet according to claim 1, wherein the insulation film layer formed on the antenna pattern is partially removed from the antenna pattern at a periphery of a portion where the IC chip is mounted.

3. The RFID inlet according to claim 1, wherein the insulation film layer is a resist used as a mask when forming the antenna pattern.

4. The RFID inlet according to claim 1, wherein the insulation film layer is a film attached to the antenna pattern.

5. An RFID tag, comprising:
the RFID inlet according to claim 1;
a shaping layer having a window and placed on the insulation film layer so as for the IC chip to be mounted inside the window;
a buffer material filled between the IC chip and the shaping layer inside the window of the shaping layer; and
a printing layer placed on the shaping layer and the IC chip.

6. The RFID tag according to claim 5, further comprising a base film layer formed between the printing layer and the shaping layer or the IC chip.

7. A method of manufacturing an RFID inlet, comprising:
forming an antenna pattern by applying a resist on a base film on which a material for the antenna pattern is formed, exposing the resist through a mask, and etching the exposed resist to form the antenna pattern with the material fro the antenna pattern;
partially removing the resist from the antenna pattern where an IC chip is to be mounted;
mounting and bonding the IC chip onto the antenna pattern where the resist is partially removed; and
filling an underfill material into gaps between the IC chip and the antenna pattern, the IC chip and the base film, and the IC chip and the resist.

8. The method for manufacturing an RFID inlet according to claim 7, wherein the resist layer is formed such that the thickness of the resist layer is thinner than the thickness of the IC chip.

9. The method for manufacturing an RFID inlet according to claim 7, wherein in the step of partially removing the resist, the resist is partially removed by irradiating a laser beam to the portion of the resist corresponding to the portion where the IC chip is mounted on the antenna pattern and its periphery.

10. The method for manufacturing an RFID inlet according to claim 7, wherein in the step of partially removing the resist, the resist is partially removed by masking the resist where the IC chip is mounted on the antenna pattern and its periphery, by exposing the masked resist with an exposure light beam having an intensity denser than the intensity of an exposure light beam used in the step of exposing the antenna pattern, and by removing the resist of the masked portion which has not been exposed by the light beam with the denser intensity.

11. A method for manufacturing an RFID tag comprising:
bonding a shaping layer, which has a window in a portion corresponding to the top surface of the IC chip and has a height of the surface approximately as high as the height of the surface of the IC chip, to the resist of the RFID inlet manufactured by according to claim 7;
filling a buffer material into gaps between the shaping layer, the base film and the IC chip; and
bonding a printing layer to the shaping layer and the IC chip so as to cover surfaces of the shaping layer and the IC chip.
